(19) United States
(12) Patent Application Publication
(10) Pub. No.: US 2026/0154477 A1
(43) Pub. Date: Jun. 4, 2026

(54) STRUCTURAL ANALYSIS APPARATUS

(71) Applicants: INSTITUTE OF SCIENCE TOKYO, Tokyo (JP); TOYOTA JIDOSHA KABUSHIKI KAISHA, Toyota-shi (JP)

(72) Inventors: Yasunobu ANDO, Tokyo-to (JP); Yuta SUZUKI, Tokyo-to (JP)

(73) Assignees: INSTITUTE OF SCIENCE TOKYO, Tokyo (JP); TOYOTA JIDOSHA KABUSHIKI KAISHA, Toyota-shi (JP)

(21) Appl. No.: 19/374,382

(22) Filed: Oct. 30, 2025

(30) Foreign Application Priority Data
Dec. 2, 2024 (JP) 2024-209312

(51) Int. Cl. G06F 30/27

(52) U.S. Cl. CPC G06F 30/27

(57) ABSTRACT

A structural analysis apparatus includes: an acquisition unit that acquires measurement data which is a result of X-ray Diffraction (XRD) analysis of a crystal structure of an analysis target; a simulation unit that performs a simulation of XRD analysis on an estimation model of the crystal structure and generates simulation data corresponding to the measurement data; an evaluation unit that calculates an R value which is an index indicating a degree of matching between the measurement data and the simulation data, and calculates an energy value of the estimation model of the crystal structure; a model estimation unit that optimizes the estimation model of the crystal structure based on the R value and the energy value that are fed back from the evaluation unit and provides the optimized estimation model of the crystal structure to the simulation unit; and an output unit that outputs at least one estimation model.

### CROSS REFERENCE TO RELATED APPLICATIONS

This application is based upon and claims the benefit of priority from Japanese patent application No. 2024-209312, filed on Dec. 2, 2024, the disclosure of which is incorporated herein in its entirety by reference.

### BACKGROUND

The present disclosure relates to a structural analysis apparatus.

A Rietveld analysis apparatus is required to quickly and highly reliably generate an estimation model of a crystal structure to be analyzed. For example, Non-patent Literature 1 discloses a technology for automating Rietveld analysis.
[Non-Patent Literature 1] Yoshihiko Ozaki et al., “Automated crystal structure analysis based on blackbox optimization”, npj Computational Materials (2020) 6:75

### SUMMARY

In Non-patent Literature 1, an estimation model of a crystal structure to be analyzed is optimized so that an R value which is an index indicating the degree of matching between measurement data, which is a result of XRD analysis of the crystal structure to be analyzed, and simulation data, which is a result of simulation of XRD analysis performed on the estimation model, shows a minimum value. However, there is a problem that when only the R value is minimized, an estimation model of an energetically unstable structure (a high energy structure) may be generated, and hence a highly reliable estimation model still cannot be generated.

The present disclosure has been made in view of the aforementioned circumstances and an object thereof is to provide a structural analysis apparatus capable of quickly generating a highly reliable estimation model of a crystal structure.

A structural analysis apparatus according to the present disclosure includes: an acquisition unit configured to acquire measurement data which is a result of X-ray Diffraction (XRD) analysis of a crystal structure of an analysis target; a simulation unit configured to perform a simulation of XRD analysis on an estimation model of the crystal structure and generate simulation data corresponding to the measurement data; an evaluation unit configured to calculate an R value which is an index indicating a degree of matching between the measurement data and the simulation data, and calculate an energy value of the estimation model of the crystal structure; a model estimation unit configured to optimize the estimation model of the crystal structure based on the R value and the energy value that are fed back from the evaluation unit and provide the optimized estimation model of the crystal structure to the simulation unit; and an output unit configured to output at least one estimation model of the crystal structure. As described above, the structural analysis apparatus according to the present disclosure can automatically optimize an estimation model not only so that the R value becomes smaller, but also so that the amount of energy of the crystal structure becomes smaller, thereby quickly generating a highly reliable estimation model of the crystal structure.

According to the present disclosure, it is possible to provide a structural analysis apparatus capable of quickly generating a highly reliable estimation model of a crystal structure.

The above and other objects, features and advantages of the present disclosure will become more fully understood from the detailed description given hereinbelow and the accompanying drawings.

### BRIEF DESCRIPTION OF DRAWINGS

FIG. 1 is a diagram showing a configuration of an example of a structural analysis apparatus according to the present disclosure;

FIG. 2 is a conceptual diagram for explaining a flow of processes performed by the structural analysis apparatus according to the present disclosure;

FIG. 3 is a flowchart showing operations performed by the structural analysis apparatus according to the present disclosure; and

FIG. 4 is a diagram showing an example of a result of analysis by the structural analysis apparatus according to the present disclosure.

### DESCRIPTION OF EMBODIMENTS

Specific embodiments to which the present disclosure is applied will be described hereinafter in detail with reference to the drawings. However, the present disclosure is not limited to the following embodiments. Further, for the clarification of the description, the following descriptions and the drawings are simplified as appropriate.

### Configuration of Structural Analysis Apparatus 100

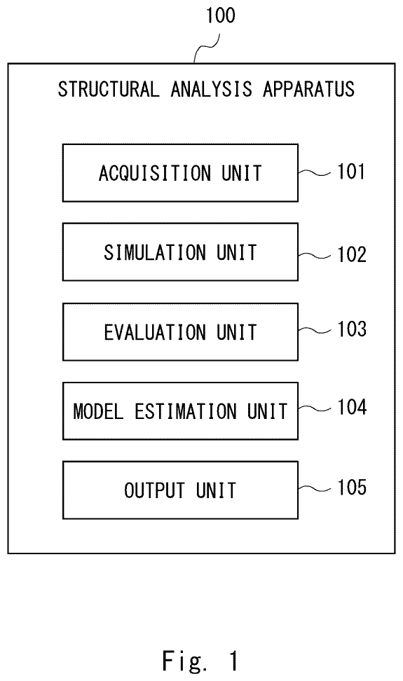

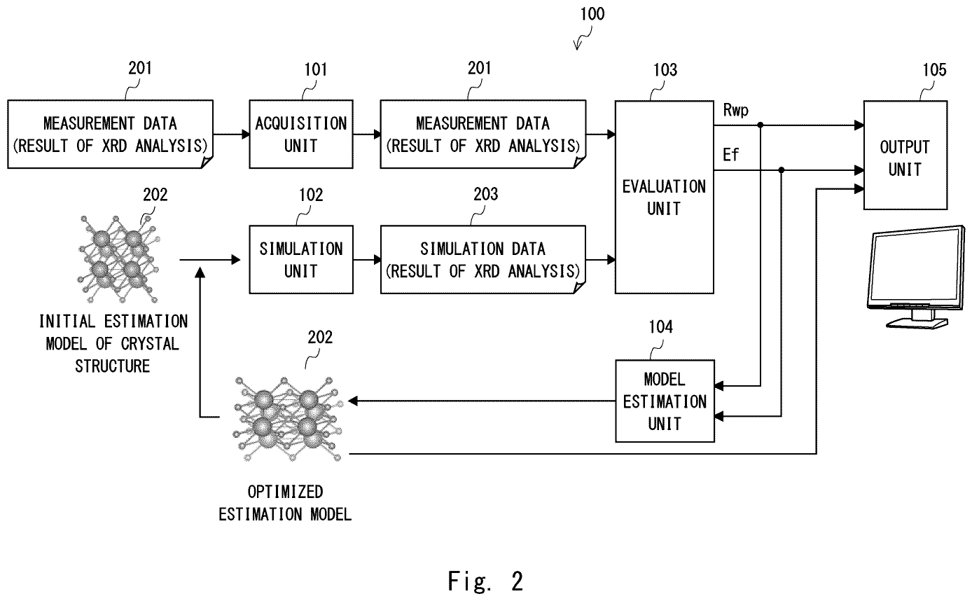

FIG. 1 is a diagram showing a configuration of an example of a structural analysis apparatus 100 according to the present disclosure. Further, FIG. 2 is a conceptual diagram for explaining a flow of processes performed by the structural analysis apparatus 100 according to the present disclosure. The structural analysis apparatus 100 according to the present disclosure is a so-called Rietveld analysis apparatus, which is an apparatus that analyzes an analysis target T such as a material and generates an estimation model of a crystal structure of the analysis target T. Note that the structural analysis apparatus 100 according to the present disclosure can automatically optimize an estimation model not only so that an R value, which is an index indicating the degree of matching between the crystal structure of the analysis target T and the estimation model, becomes smaller, but also so that the amount of energy of the crystal structure becomes smaller, thereby quickly generating a highly reliable estimation model of the crystal structure. The details of the above configuration will be described below.

The structural analysis apparatus 100 shown in FIG. 1 includes an acquisition unit 101, a simulation unit 102, an evaluation unit 103, a model estimation unit 104, and an output unit 105.

The acquisition unit 101 acquires measurement data 201 which is a result of X-ray Diffraction (XRD) analysis of the crystal structure of the analysis target T.

The simulation unit 102 performs a simulation of XRD analysis on an initialized estimation model 202 of the crystal structure, and generates simulation data 203 corresponding to the measurement data 201.

The evaluation unit 103 compares the measurement data 201 with the simulation data 203, and calculates an R value Rwp which is an index indicating the degree of matching between the measurement data 201 and the simulation data 203. Further, the evaluation unit 103 calculates an energy value Ef of the estimation model 202 of the crystal structure from the simulation data 203 using, for example, Density Functional Theory (DFT).

Normally, the degree of matching between the measurement data 201 and the simulation data 203 increases as the R value Rwp becomes lower, while it decreases as the R value Rwp becomes higher. Further, the crystal structure becomes stable as the energy value Ef becomes lower, while it becomes unstable as the energy value Ef becomes higher. That is, the crystal structure becomes physically more plausible as the energy value Ef becomes lower. Therefore, the crystal structure tends to become a structure having a low energy value Ef. Therefore, the lower the R value Rwp and the lower the energy value Ef, the higher the possibility that the estimation model 202 of the crystal structure will be close to the crystal structure of the analysis target T. In other words, the lower the R value Rwp and the lower the energy value Ef, the higher the reliability of the estimation model 202 of the crystal structure.

The model estimation unit 104 optimizes the estimation model 202 used to calculate the R value Rwp and the energy value Ef based on the R value Rwp and the energy value Ef fed back from the evaluation unit 103, and generates an optimized estimation model 202 of the crystal structure.

For example, the model estimation unit 104 optimizes the estimation model 202 used to calculate the R value Rwp and the energy value Ef in such a way that the R value Rwp and the energy value Ef are expected to become even lower, and generates an optimized estimation model 202 of the crystal structure. More specifically, the model estimation unit 104 predicts model parameters with which the R value Rwp and the energy value Ef become even lower from a plurality of combinations of the estimation model 202 of the crystal structure and the R value Rwp and the energy value Ef corresponding thereto, and generates an estimation model 202 of the crystal structure optimized in accordance with the predicted model parameters. The estimation model 202 of the crystal structure optimized by the model estimation unit 104 is provided to the simulation unit 102 instead of an initialized estimation model 202 of the crystal structure.

Note that the model estimation unit 104 may be configured to perform machine learning using a plurality of combinations of the estimation model 202 of the crystal structure and the R value Rwp and the energy value Ef corresponding thereto. In this case, the model estimation unit 104 can optimize the estimation model 202 used to calculate the R value Rwp and the energy value Ef in such a way that the R value Rwp and the energy value Ef are expected to become even lower by using a trained model generated by the machine learning. More specifically, the model estimation unit 104 can predict model parameters with which the R value Rwp and the energy value Ef become even lower by using a trained model generated by the machine learning, and generate an estimation model 202 of the crystal structure optimized in accordance with the predicted model parameters.

However, the model estimation unit 104 is not limited to performing machine learning by using a combination of the estimation model 202 of the crystal structure and the R value Rwp and the energy value Ef corresponding thereto, and may instead perform machine learning by using a combination of the estimation model 202 of the crystal structure and the R value Rwp corresponding thereto or a combination of the estimation model 202 of the crystal structure and the energy value Ef corresponding thereto.

The simulation unit 102 performs a simulation of XRD analysis on the optimized estimation model 202 of the crystal structure, and regenerates the simulation data 203 corresponding to the measurement data 201. The evaluation unit 103 compares the measurement data 201 with the regenerated simulation data 203, and calculates the R value Rwp which is an index indicating the degree of matching between the measurement data 201 and the regenerated simulation data 203. Further, the evaluation unit 103 calculates the energy value Ef of the estimation model 202 of the crystal structure from the regenerated simulation data 203. The model estimation unit 104 optimizes the estimation model 202 of the crystal structure based on the R value Rwp and the energy value Ef fed back from the evaluation unit 103, and generates an optimized estimation model 202 of the crystal structure.

The optimization of the estimation model by the model estimation unit 104, the simulation of the estimation model by the simulation unit 102, and the evaluation between the measurement data 201 and the simulation data 203 by the evaluation unit 103 are repeated until the R value Rwp and the energy value Ef converge.

The output unit 105 outputs information about a plurality of the optimized estimation models 202 of the crystal structure. Alternatively, the output unit 105 may output information about the estimation model 202 indicating the lowest possible R value Rwp and the lowest possible energy value Ef among a plurality of the optimized estimation models 202 of the crystal structure. The output content of the output unit 105 is displayed, for example, on a monitor.

Note that the output unit 105 may display a plurality of the optimized estimation models 202 of the crystal structure (or their R values Rwp and energy values Ef) on the monitor, and may highlight the estimation model 202 (or its R value Rwp and energy value Ef) indicating the lowest possible R value Rwp and the lowest possible energy value Ef among the plurality of the optimized estimation models 202 of the crystal structure.

As described above, the structural analysis apparatus 100 according to the present disclosure can automatically optimize an estimation model not only so that the R value, which is an index indicating the degree of matching between the crystal structure of the analysis target T and the estimation model, becomes smaller, but also so that the amount of energy of the crystal structure becomes smaller, thereby quickly generating a highly reliable estimation model of the crystal structure.

### Operation of Structural Analysis Apparatus 100

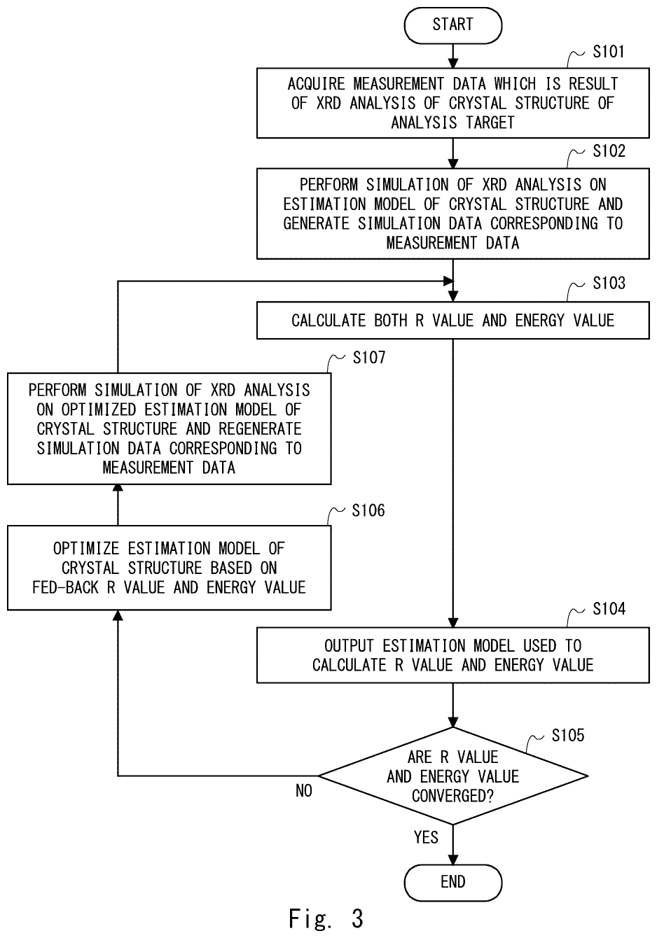

FIG. 3 is a flowchart showing operations performed by the structural analysis apparatus 100.

First, the structural analysis apparatus 100 acquires the measurement data 201 which is a result of XRD analysis of the crystal structure of the analysis target T (Step S101).

After that, the structural analysis apparatus 100 performs a simulation of XRD analysis on an initialized estimation model 202 of the crystal structure, and generates the simulation data 203 corresponding to the measurement data 201 (Step S102).

After that, the structural analysis apparatus 100 compares the measurement data 201 with the simulation data 203, and calculates the R value Rwp which is an index indicating the degree of matching between the measurement data 201 and the simulation data 203 (Step S103). Further, the structural analysis apparatus 100 calculates the energy value Ef of the estimation model 202 of the crystal structure from the simulation data 203 using, for example, DFT (Step S103).

After that, the structural analysis apparatus 100 outputs the estimation model 202 of the crystal structure used to calculate the R value Rwp and the energy value Ef (Step S104).

After that, if both the R value Rwp and the energy value Ef are not converged (NO in Step S105), the structural analysis apparatus 100 optimizes the estimation model 202 used to calculate the R value Rwp and the energy value Ef based on the fed-back R value Rwp and energy value Ef, and generates an optimized estimation model 202 of the crystal structure (Step S106). More specifically, the structural analysis apparatus 100 predicts model parameters with which the R value Rwp and the energy value Ef become even lower from a plurality of combinations of the estimation model 202 of the crystal structure and the R value Rwp and the energy value Ef corresponding thereto, and generates an estimation model 202 of the crystal structure optimized in accordance with the predicted model parameters (Step S106).

After that, the structural analysis apparatus 100 performs a simulation of XRD analysis on the optimized estimation model 202 of the crystal structure, and regenerates the simulation data 203 corresponding to the measurement data 201 (Step S107).

After that, the structural analysis apparatus 100 compares the measurement data 201 with the regenerated simulation data 203, and calculates the R value Rwp which is an index indicating the degree of matching between the measurement data 201 and the regenerated simulation data 203 (Step S103). Further, the structural analysis apparatus 100 calculates the energy value Ef of the estimation model 202 of the crystal structure from the regenerated simulation data 203 (Step S103).

After that, the structural analysis apparatus 100 outputs the estimation model 202 of the crystal structure used to calculate the R value Rwp and the energy value Ef (Step S104).

The structural analysis apparatus 100 repeats the optimization of the estimation model 202 until both the R value Rwp and the energy value Ef converge, and terminates the process when both the R value Rwp and the energy value Ef converge and no longer decrease (YES in Step S105).

In the present disclosure, a description has been given of an example in which the structural analysis apparatus 100 terminates structural analysis when both the R value Rwp and the energy value Ef converge and no longer decrease even if the structural analysis is repeated. However, the present disclosure is not limited thereto. For example, the structural analysis apparatus 100 may terminate the structural analysis when the number of generated estimation models reaches a predetermined number.

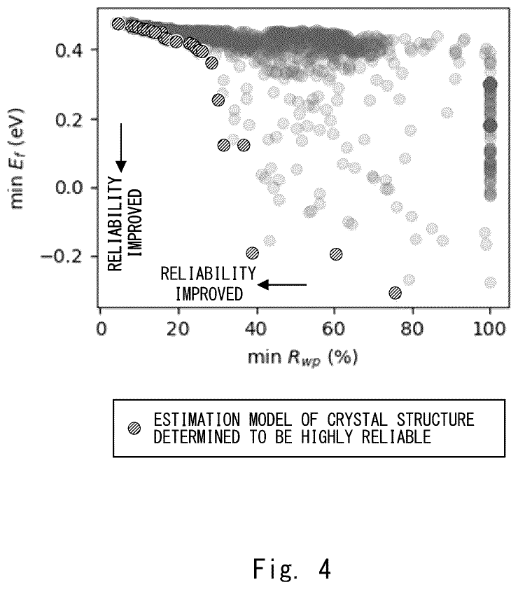

FIG. 4 is a diagram showing an example of a result of analysis by the structural analysis apparatus 100. The result of analysis by the structural analysis apparatus 100 as shown in FIG. 4 is displayed, for example, on a monitor. In the example of FIG. 4, plane coordinates in which the horizontal axis indicates the R value Rwp of the estimation model 202 and the vertical axis indicates the energy value Ef of the estimation model 202 are shown.

In the example of FIG. 4, among a plurality of plots of the estimation models 202, a plurality of the plots (boundary plots) located in the outer edge of a plot group are highlighted as plots of the estimation models 202 having high reliability. In the estimation models 202 represented by the plurality of boundary plots, the R value Rwp is extremely low, the energy value Ef is extremely low, or the R value Rwp and the energy value Ef are low overall. For example, a user of the structural analysis apparatus 100 can suitably select one of the estimation models 202 of the plurality of highlighted boundary plots and employ it as a candidate of the crystal structure of the analysis target T.

As described above, the structural analysis apparatus 100 according to the present disclosure can automatically optimize an estimation model not only so that the R value, which is an index indicating the degree of matching between the crystal structure of the analysis target T and the estimation model, becomes smaller, but also so that the amount of energy of the crystal structure becomes smaller, thereby quickly generating a highly reliable estimation model of the crystal structure.

Note that, in the present disclosure, some or all of the processes performed by the structural analysis apparatus 100 may be implemented by causing a Central Processing Unit (CPU) to execute a computer program.

The above-described program includes instructions (or software codes) that, when loaded into a computer, cause the computer to perform one or more of the functions described in the embodiments. The program may be stored in a non-transitory computer readable medium or a tangible storage medium. By way of example, and not a limitation, non-transitory computer readable media or tangible storage media can include a Random-Access Memory (RAM), a Read-Only Memory (ROM), a flash memory, a Solid-State Drive (SSD) or other types of memory technologies, a CD-ROM, a Digital Versatile Disc (DVD), a Blu-ray (Registered Trademark) disc or other types of optical disc storage, a magnetic cassette, a magnetic tape, and a magnetic disk storage or other types of magnetic storage devices. The program may be transmitted on a transitory computer readable medium or a communication medium. By way of example, and not a limitation, transitory computer readable media or communication media can include electrical, optical, acoustical, or other forms of propagated signals.

Although the present disclosure has been described with reference to embodiments, the present disclosure is not limited to the above-described embodiments. Various changes that may be understood by those skilled in the art may be made to the configurations and details of the present disclosure within the scope of the present disclosure. Further, each of the embodiments may be combined with at least one of the other embodiments as appropriate.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A structural analysis apparatus comprising:
an acquisition unit configured to acquire measurement data which is a result of X-ray Diffraction (XRD) analysis of a crystal structure of an analysis target;
a simulation unit configured to perform a simulation of XRD analysis on an estimation model of the crystal structure and generate simulation data corresponding to the measurement data;
an evaluation unit configured to calculate an R value which is an index indicating a degree of matching between the measurement data and the simulation data, and calculate an energy value of the estimation model of the crystal structure;
a model estimation unit configured to optimize the estimation model of the crystal structure based on the R value and the energy value that are fed back from the evaluation unit and provide the optimized estimation model of the crystal structure to the simulation unit; and
an output unit configured to output at least one estimation model of the crystal structure.

2. The structural analysis apparatus according to claim 1, wherein the model estimation unit performs machine learning using a combination of the estimation model of the crystal structure and the R value and the energy value corresponding to the estimation model of the crystal structure, and optimizes the estimation model of the crystal structure so that the R value and the energy values become lower by using a trained model generated by the machine learning.

3. The structural analysis apparatus according to claim 1, wherein the evaluation unit calculates the energy value of the estimation model of the crystal structure by using Density Functional Theory (DFT).

4. The structural analysis apparatus according to claim 1, wherein the output unit displays information about the at least one estimation model of the crystal structure on a monitor.

5. The structural analysis apparatus according to claim 1, wherein the output unit highlights, among a plurality of plots respectively indicating a plurality of the estimation models of the crystal structure shown on plane coordinates in which a horizontal axis indicates the R value and a vertical axis indicates the energy value, a plurality of the plots located in an outer edge of a plot group on the monitor.
